(19) United States
(12) Patent Application Publication
(10) Pub. No.: US 2021/0048345 A1
(43) Pub. Date: Feb. 18, 2021

(54) HETEROGENEOUSLY INTEGRATED THERMAL INFRARED SENSING MEMBER AND THERMAL INFRARED SENSOR

(71) Applicant: MEI-YEN LEE, HSIN CHU (TW)

(72) Inventor: BRUCE C. S. CHOU, HSIN CHU (TW)

(21) Appl. No.: 16/989,438

(22) Filed: Aug. 10, 2020

(30) Foreign Application Priority Data
Aug. 12, 2019 (TW) 108128510
Jul. 22, 2020 (CN) 202010709601.5

(51) Int. Cl. G01J 5/14; H01L 35/32

(52) U.S. Cl. CPC G01J 5/14; G01J 2005/123; H01L 35/325

(57) ABSTRACT

A heterogeneously integrated thermal infrared sensing member includes: a substrate; a chamber disposed in or on the substrate; and one or multiple thermal couples formed using materials formed on a sacrificial substrate and transferred to a location above the chamber by way of bonding the substrate to one portion of the materials formed on the sacrificial substrate, removing the sacrificial substrate, and patterning and interconnecting another portion of the material, wherein the thermal couple includes a first conductor and a second conductor, first ends of the first conductor and the second conductor of the thermal couple are connected at a hot junction disposed above the chamber, and second ends of the first conductor and the second conductor of the thermal couple are located at a cold junction region disposed around the chamber.

### CROSS-REFERENCE TO RELATED APPLICATIONS

This application claims priorities of No. 108128510 filed in Taiwan R.O.C. on Aug. 12, 2019 and No. 202010709601.5 filed in China on Jul. 22, 2020 under 35 USC 119, the entire contents of which are hereby incorporated by reference.

### BACKGROUND OF THE INVENTION

### Field of the Invention

This disclosure relates to a thermal infrared sensing member and a thermal infrared sensor, and more particularly to a heterogeneously integrated thermal infrared sensing member and a thermal infrared sensor.

### Description of the Related Art

Recently, thermal infrared sensing members, such as thermal couples, are frequently used to measure the temperature according to the following principle. A diffusion current is generated according to a temperature difference between a cold junction (the other connection portion between the conductors) and a heated hot junction of the connection portion between the conductors. In order to eliminate the diffusion current, the thermal couple needs to provide a considerable counter electromotive force, which is the Seedback voltage. By measuring the Seedback voltage, the temperature difference between the two ends of the thermal couple can be obtained to calibrate the temperature. The Seedback voltage is determined by the product of the temperature difference between two ends and the Seedback coefficient of the two conductors. Multiple pairs of thermal couples are serially connected together to form a thermopile. Thus, the thermal electromotive force of the thermopile is equal to the product of the Seedback voltage of one single thermal couple and the number of serially connected thermal couples.

Regarding to the current technology, if the thermopile is to be integrated with the semiconductor manufacturing process, the most frequently used materials include silicon and polysilicon, for example. In the complementary metal-oxide semiconductor (CMOS), the front end of the silicon substrate is defined with polysilicon (high-temperature manufacturing process), and the back end of the silicon substrate is defined with metal layers (low-temperature manufacturing process). Finally, the structure is released to remove one portion of the silicon substrate as the sacrificial layer to form a chamber, such as that disclosed in Taiwan Patent No. 451260. The drawback of such the method is that no circuit or circuitry can be configured under the structure, which is the chamber. Such the technology encounters the more serious trouble because the circuit or circuitry can be placed beside the thermopile, so that the fill factor (FF) of each pixel representing the ratio of the sensing area of the pixel to the total area of the pixel is significantly reduced, wherein the higher FF represents the higher quality factor. Thus, the prior art has the drawback of the low FF, and still needs to be improved. Also, based on this scheme, it can't be used for a high-density array device with the small pixel sensor design having the pixel pitch smaller than 30 μm or even 20 μm, for example.

### BRIEF SUMMARY OF THE INVENTION

An objective of this disclosure is to provide a heterogeneously integrated thermal infrared sensing member and a thermal infrared sensor to increase the fill factor, shorten the signal transmission path, increase the signal-to-noise ratio, effectively solve the problem and prevent the sensing circuit from being affected by the high-temperature manufacturing process for the polysilicon.

An embodiment of this disclosure provides a heterogeneously integrated thermal infrared sensing member including: a substrate; a chamber disposed in or on the substrate; and one or multiple thermal couples formed using materials formed on a sacrificial substrate and transferred to a location above the chamber by way of bonding the substrate to one portion of the materials formed on the sacrificial substrate, removing the sacrificial substrate, and patterning and interconnecting another portion of the materials, wherein the thermal couple or each of the thermal couples includes a first conductor and a second conductor, first ends of the first conductor and the second conductor of the thermal couple are connected at a hot junction region disposed above the chamber, and second ends of the first conductor and the second conductor of the thermal couple are located at a cold junction region disposed around the chamber.

Another embodiment of this disclosure further provides a thermal infrared sensor including multiple ones of the heterogeneously integrated thermal infrared sensing members. The heterogeneously integrated thermal infrared sensing members are arranged in a two-dimensional array to sense a thermal image, and share the substrate.

With the above-mentioned embodiments, two wafers are bonded to manufacture the thermal infrared sensing member and the thermal infrared sensor, wherein the circuit/circuitry and cavity are formed on the lower wafer (first initial structure) using the CMOS manufacturing process (at the temperature ranging from about 300 to 400° C.), and the upper wafer (second initial structure) is formed using the polysilicon manufacturing process (at the temperature ranging from about 600 to 700° C.). The two wafers are formed in different manufacturing process conditions, and are bonded together so that the patterning and interconnect formation processes can be performed. So, the circuit/circuitry is free from being destroyed by the too-high temperature in the manufacturing process. Because the circuit/circuitry can be formed below the chamber, the value of FF can be very high, the signal transmission path is shortened, and the signal-to-noise ratio is increased. In addition, the heterogeneous integration technology makes it possible to stack the polysilicon, which requires the high-temperature manufacturing process, above or on the CMOS wafer.

Further scope of the applicability of this disclosure will become apparent from the detailed description given hereinafter. However, it should be understood that the detailed description and specific examples, while indicating preferred embodiments of this disclosure, are given by way of illustration only, since various changes and modifications within the spirit and scope of this disclosure will become apparent to those skilled in the art from this detailed description.

### BRIEF DESCRIPTION OF THE SEVERAL VIEWS OF THE DRAWINGS

FIG. 1A is a schematic top view showing a thermal infrared sensor according to a preferred embodiment of this disclosure.

FIG. 1B is a schematic top view showing the thermal infrared sensing member of FIG. 1A.

FIG. 1C is a schematic partial top view showing the thermal infrared sensing member of FIG. 1A.

FIGS. 2A to 2J are schematically cross-sectional views showing structures taken along the line CL-CL of FIG. 1B corresponding to steps of the method of manufacturing the thermal infrared sensing member of the first embodiment.

FIGS. 3A to 3L are schematically cross-sectional views showing structures taken along the line CL-CL of FIG. 1B corresponding to steps of the method of manufacturing the thermal infrared sensing member of the second embodiment.

FIGS. 4A to 4H are partially enlarged schematic top views showing structures corresponding to some steps of the method of manufacturing the thermal infrared sensing member of the second embodiment.

FIG. 5A is a schematically partial cross-sectional view showing the structure corresponding to the line PL-PL of FIG. 4G.

FIG. 5B is a schematically partial cross-sectional view showing the structure of the modified example corresponding to FIG. 5A.

FIG. 6A is a schematically cross-sectional view showing the structure of a first modified example of the thermal infrared sensor of FIG. 1A.

FIG. 6B is a schematically cross-sectional view showing bonding of the thermal infrared sensor of FIG. 6A.

FIG. 6C is a schematically cross-sectional view showing a second modified example of the thermal infrared sensor of FIG. 1A.

FIGS. 7A to 7D are schematically cross-sectional views showing structures taken along the line CL-CL of FIG. 1B corresponding to steps of the method of manufacturing the thermal infrared sensing member of the third embodiment.

FIGS. 8A and 8B are schematically cross-sectional views showing a modified example of FIGS. 7A and 7B.

FIGS. 9A to 9D are schematically cross-sectional views showing structures taken along the line CL-CL of FIG. 1B corresponding to steps of the method of manufacturing the thermal infrared sensing member of the fourth embodiment.

FIGS. 10A and 10B are schematically cross-sectional views showing a modified example of FIGS. 9A and 9B.

### DETAILED DESCRIPTION OF THE INVENTION

The spirit of this disclosure is to adopt the heterogeneous integration technology to firstly form the circuit/circuitry (containing multi metal layers) in or on the wafer using the manufacturing process of the integrated circuit (more particularly CMOS), and then a cavity, chamber or predetermined sacrificial layer structure is defined on or in the wafer using the back-end manufacturing process. In addition, one or multiple conductor layers are formed on another wafer. Then, the two wafers are bonded together by the wafer bonding technology. Next, the lithography process for material patterning and the interconnect formation process are performed so that the thermal infrared sensing member or thermal infrared sensor (array element) can be formed.

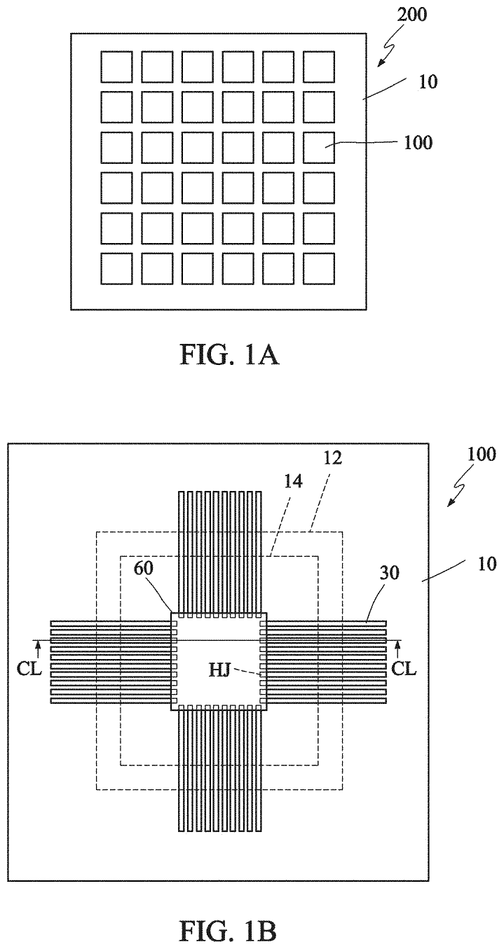

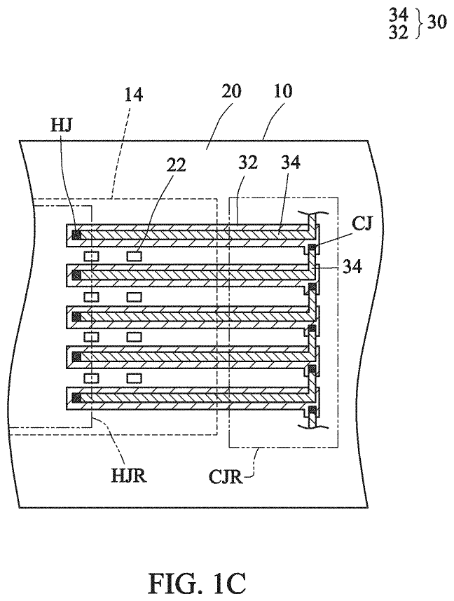

FIG. 1A is a schematic top view showing a thermal infrared sensor according to a preferred embodiment of this disclosure. Referring to FIG. 1A, a thermal infrared sensor 200 includes thermal infrared sensing members 100 arranged in a two-dimensional array to sense a thermal image. The thermal infrared sensing members 100 share the same substrate 10, such as a silicon substrate.

FIG. 1B is a schematic top view showing the thermal infrared sensing member of FIG. 1A. FIG. 1C is a schematic partial top view showing the thermal infrared sensing member of FIG. 1A. Referring to FIGS. 1B and 1C, the thermal infrared sensing member 100 includes the substrate 10, wherein the substrate may be a semiconductor substrate; an insulation substrate, such as a glass substrate or the like; or a thin film transistor substrate. The substrate 10 is formed with a sensing circuit 12, which includes transistors and metal interconnections electrically connected together. A chamber 14 is formed above the sensing circuit 12. Multiple thermal couples 30 on four sides of the chamber 14 are serially connected together, and finally electrically connected to output pads (not shown) or directly connected to the sensing circuit 12, so that the sensing circuit 12 reads the Seedback voltage or performs the further processing. For example, a first conductor 32 and a second conductor 34 of the same pair of thermal couples 30 above the chamber 14 or directly above the thermal insulation zone are connected at a hot junction region HJR where hot junctions HJ are formed, and the first conductor 32 and the second conductor 34 of the neighboring pairs of thermal couples 30 in the thermal draining zone outside the thermal insulation zone are located at a cold junction region CJR where cold junctions CJ are formed. A black body layer 60 covers the hot junction region HJR and absorbs the radiation heat. The radiation heat absorbed by the black body layer 60 can increase the temperature of the hot junction region HJR due to the low solid thermal conduction, and generate be a temperature difference between the hot junction region HJR and the cold junction region CJR. In the above-mentioned example, the sensing circuit 12 and the chamber 14 are disposed in the substrate 10. In another example, the sensing circuit 12 and the chamber 14 may also be formed on the substrate 10.

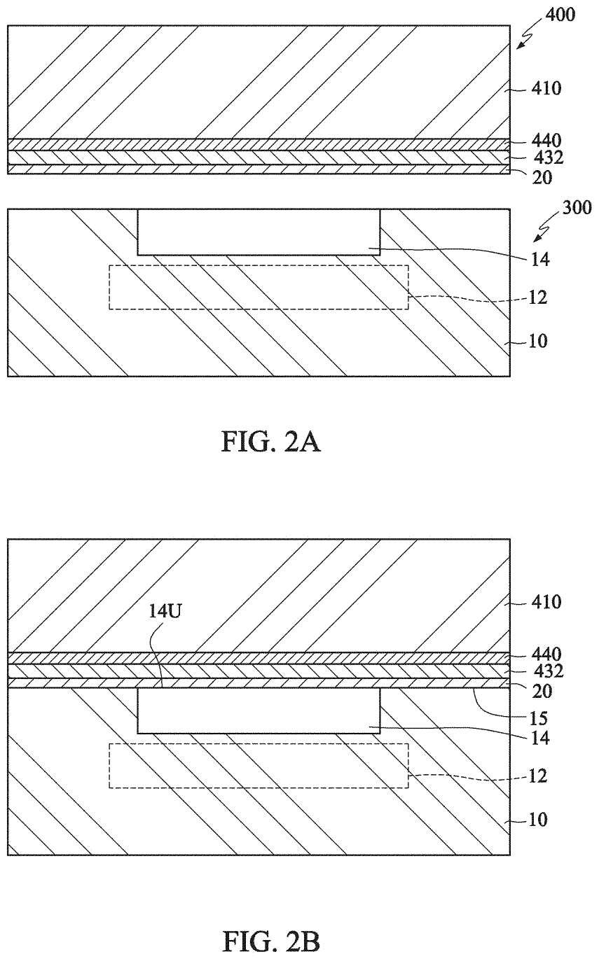

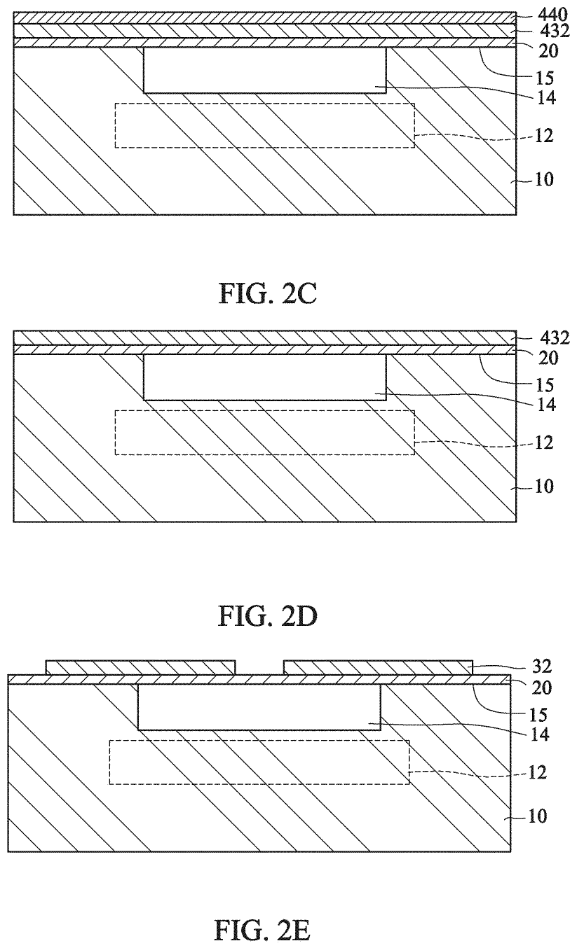

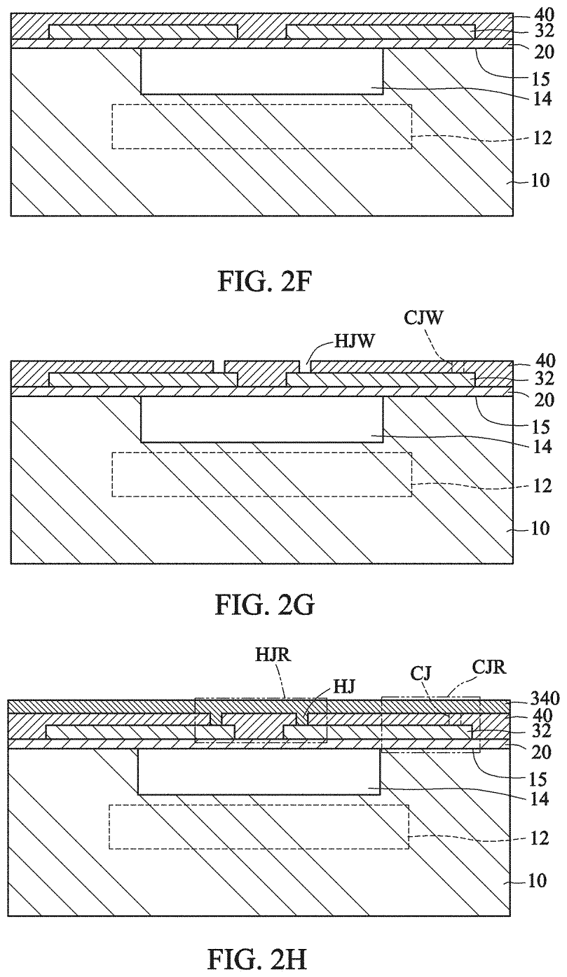

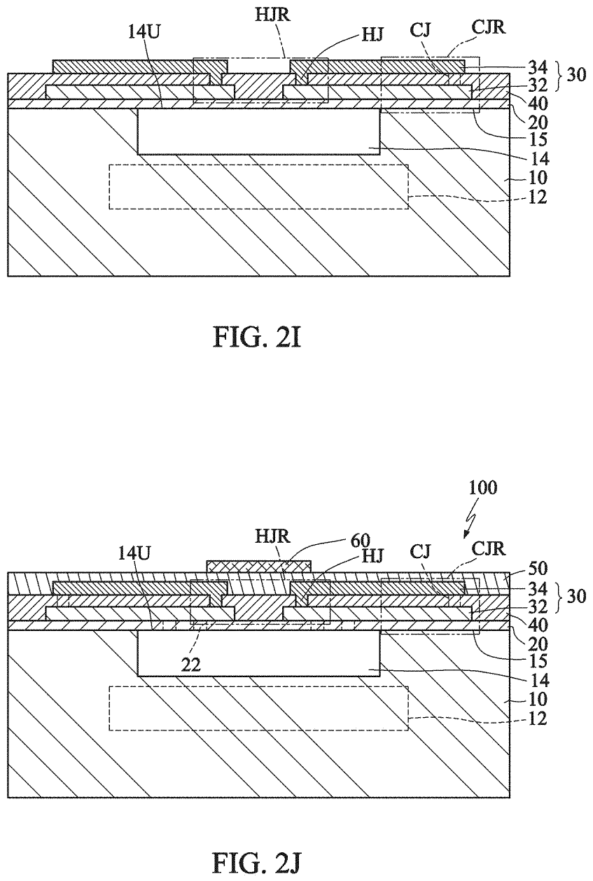

FIGS. 2A to 2J are schematically cross-sectional views showing structures taken along the line CL-CL of FIG. 1B corresponding to steps of the method of manufacturing the thermal infrared sensing member of the first embodiment. As shown in FIG. 2A, a first initial structure 300 and a second initial structure 400 are provided. The first initial structure 300 includes a substrate (e.g., silicon substrate, silicon wafer or any other substrate mentioned hereinabove) 10, which has a sensing circuit 12 and a chamber 14. The sensing circuit 12 is disposed below or under the chamber 14. The second initial structure 400 includes: a first insulating layer 20; a first conductor layer 432 disposed on the first insulating layer 20; a dielectric layer 440 disposed on the first conductor layer 432; and a second substrate or a sacrificial substrate (e.g., silicon substrate, silicon wafer or any other substrate mentioned hereinabove) 410 disposed on the dielectric layer 440.

As shown in FIG. 2B, the first insulating layer 20 of the second initial structure 400 and the substrate 10 of the first initial structure 300 are bonded together (by way of pressing and heating), so that the first insulating layer 20 is disposed on the substrate 10 and covers the chamber 14 to serve as an upper wall surface 14U of the chamber 14, and a bonding interface (e.g., a wafer bonding interface) 15, which is a chemical bond with the stronger bonding force, is formed between the first insulating layer 20 and the substrate 10. The upper wall surface 14U does not have the wafer bonding interface. It is worth noting that the wafer bonding may be present between two wafers to manufacture multiple thermal infrared sensors 200. Another feature of this disclosure is that blinding bonding can be performed between the two wafers, and no special alignment machine or technology is needed, so that the bonding yield can be further increased, and the cost can be further decreased. Of course, with the progress of the alignment bonding technology, the alignment bonding technology is also applicable to this disclosure.

As shown in FIG. 2C, the second substrate 410 is removed. As shown in FIG. 2D, the dielectric layer 440 is removed. As shown in FIG. 2E, the first conductor layer 432 is patterned to form first conductors 32 disposed on the first insulating layer 20.

As shown in FIG. 2F, a second insulating layer 40 is formed on the first conductors 32 and the first insulating layer 20. As shown in FIG. 2G, the second insulating layer 40 is patterned to form hot junction windows HJW and cold junction windows CJW. In this example, the hot junction window HJW and the cold junction window CJW are located on a same horizontal surface (i.e., located on a same height or level). As shown in FIG. 2H, a second conductor layer 340 is formed on the second insulating layer 40, so that the second conductor layer 340 is electrically connected to the first conductors 32 through the hot junction windows HJW and the cold junction windows CJW. As shown in FIG. 2I, the second conductor layer 340 is patterned to form second conductors 34, wherein the first conductors 32 and the second conductors 34 form the thermal couples 30, the thermal couples 30 are serially connected together to form a thermopile (one single thermal couple 30 may also be implemented in this disclosure), and are electrically connected to the sensing circuit 12. Each thermal couple 30 includes the first conductor 32 and the second conductor 34. The first conductor 32 and the second conductor 34 of each thermal couple 30 are connected at a hot junction region HJR disposed above the chamber 14, and the two adjacent thermal couples 30 are connected at a cold junction region CJR away from the chamber 14. In other words, first ends of the first conductor 32 and the second conductor 34 of the thermal couple 30 are connected at a hot junction region HJR disposed above the chamber 14, and second ends of the first conductor 32 and the second conductor 34 of the thermal couple 30 are located at a cold junction region CJR disposed around the chamber 14.

Therefore, the steps in FIGS. 2F to 2I can be generalized as follows. The first conductors 32 are used to form the thermal couples 30, the thermal couples 30 are serially connected together to form the thermopile, each thermal couple 30 includes the first conductor 32 and the second conductor 34 disposed above the first conductor 32, the first conductor 32 and the second conductor 34 of each thermal couple 30 are connected at a hot junction region HJR disposed above the chamber 14, and the two adjacent thermal couples 30 are connected at a cold junction region CJR away from the chamber 14.

Next, as shown in FIG. 2J, a protection layer 50 is formed on the second insulating layer 40 and the second conductors 34, and covers the hot junction region HJR and the cold junction region CJR. Of course, the black body layer 60 may also be formed on the protection layer 50, the black body layer 60 for absorbing radiation heat covers the hot junction region HJR, but does not cover the cold junction region CJR. The steps in FIG. 2C to FIG. 2J can be generalized as the sub-step of using the second initial structure 400 to form one or multiple thermal couples (or one thermopile).

Referring to FIGS. 1C and 2J, the manufacture method of the above-mentioned thermal infrared sensing member 100 may further include the following step of forming openings 22, which are disposed on the first insulating layer 20 and penetrate through the first insulating layer 20 to communicate with the chamber 14, thereby increasing the thermal resistance, which is preferably larger. If the protection layer 50 also covers the first insulating layer 20, then the openings 22 may further penetrate through the protection layer 50.

Therefore, as shown in FIGS. 2J, 2B and 1C, the heterogeneously integrated thermal infrared sensing member 100 in this embodiment includes the substrate 10, the first insulating layer 20, the plurality of thermal couples 30 and the protection layer 50. It is worth noting that the first insulating layer 20 and the protection layer 50 are not necessarily essential components for implementing this embodiment, and there are also many possible configurations. The substrate 10 has the sensing circuit 12 and the chamber 14, and the sensing circuit 12 is disposed below or under the chamber 14. The first insulating layer 20 is disposed on the substrate 10 and covers the chamber 14 to serve as the upper wall surface 14U of the chamber 14, and the bonding interface 15 is formed between the first insulating layer 20 and the substrate 10. The thermal couples 30 are serially connected together to form the thermopile, each thermal couple 30 includes the first conductor 32 and the second conductor 34 disposed above the first conductor 32, the first conductor 32 and the second conductor 34 of each thermal couple 30 are connected at a hot junction region HJR disposed above the chamber 14, and the two adjacent thermal couples 30 are connected at a cold junction region CJR away from the chamber 14. The protection layer 50 covers the hot junction region HJR and the cold junction region CJR. The thermal infrared sensing member 100 may further include the black body layer 60, which is for absorbing radiation heat and disposed on the protection layer 50, and covers the hot junction region HJR, but does not cover the cold junction region CJR. The second conductors 34 are disposed above the first conductors 32 with the second insulating layer 40 disposed between the conductors 32 and 34. In addition, the openings 22 are formed on the first insulating layer 20, and penetrate through the first insulating layer 20 to communicate with the chamber 14. The material of the first conductor 32 includes, for example, silicon, such as P/N-type polysilicon. The material of the second conductor 34 includes metal, for example. The two ends of the first one of the conductors 32 and the last one of the conductors 34 at the cold junction region CJR are electrically connected to the sensing circuit 12. In this example, the sensing circuit 12 may include multiple active devices and/or passive devices and metal connections for achieving the electrical connections. For example, MOS elements and metal wires are provided to form the circuit system (circuitry). Because the circuitry may be destroyed by the high temperature in the polysilicon's high-temperature manufacturing process, the sensing circuit 12 in this example does not encounter the polysilicon's high-temperature manufacturing process and cannot be destroyed. That is, the sensing circuit 12 and polysilicon are formed in different stages (on different wafers), and the two wafers are bonded together by way of wafer bonding. The sensing circuit 12 may also be embedded into the substrate 10 and is not exposed to the chamber 14 to obtain the protection. In addition, the sensing circuit 12 may be electrically connected to the thermal couple 30 through the metal wire(s), and the area of the horizontal direction of the sensing circuit 12 may be greater than, equal to or smaller than the area of the horizontal direction of the chamber 14. In addition, the chamber 14 is formed in the substrate 10. It is also possible to say that the thermal infrared sensing member 100 includes the chamber 14. According to the above-mentioned description, the material of the thermal couple 30 (the material of the first conductor layer 432) is formed on another substrate (second substrate 410) and transferred to a location above the chamber 14 by way of bonding.

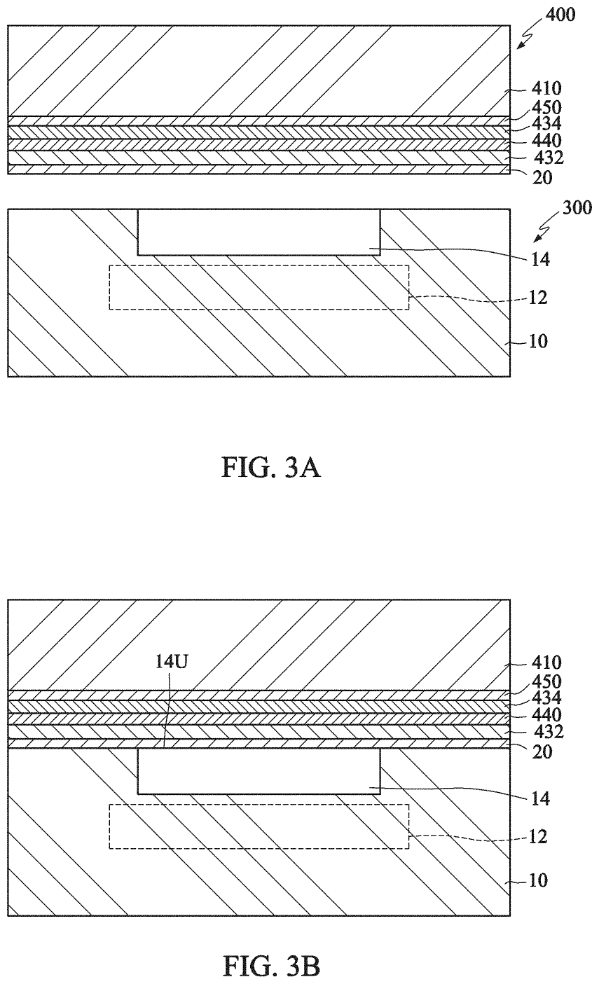

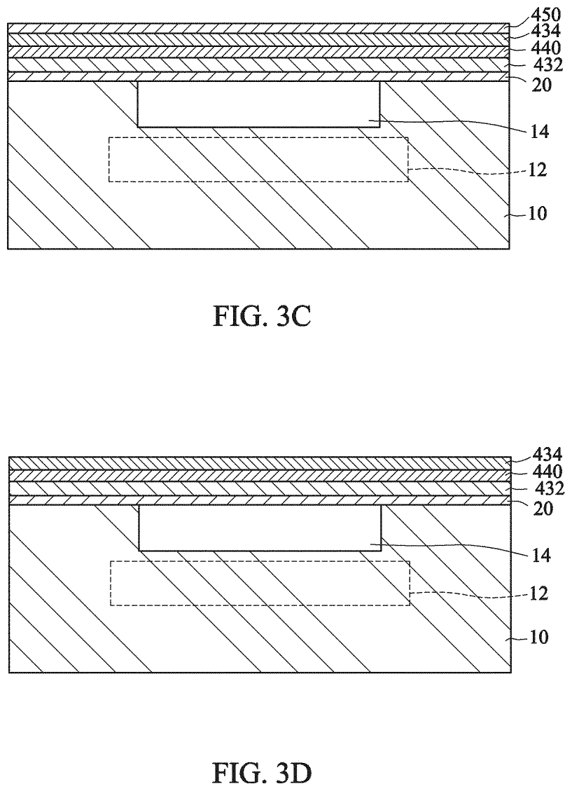

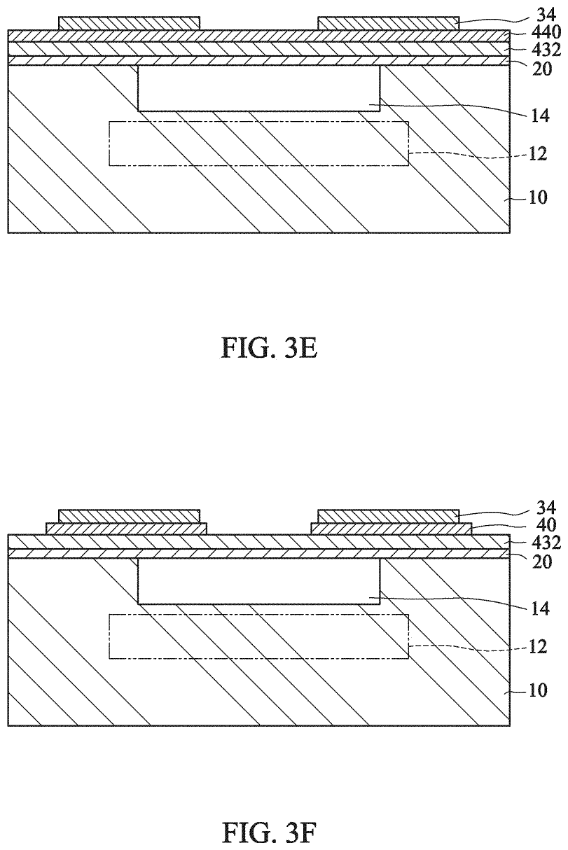

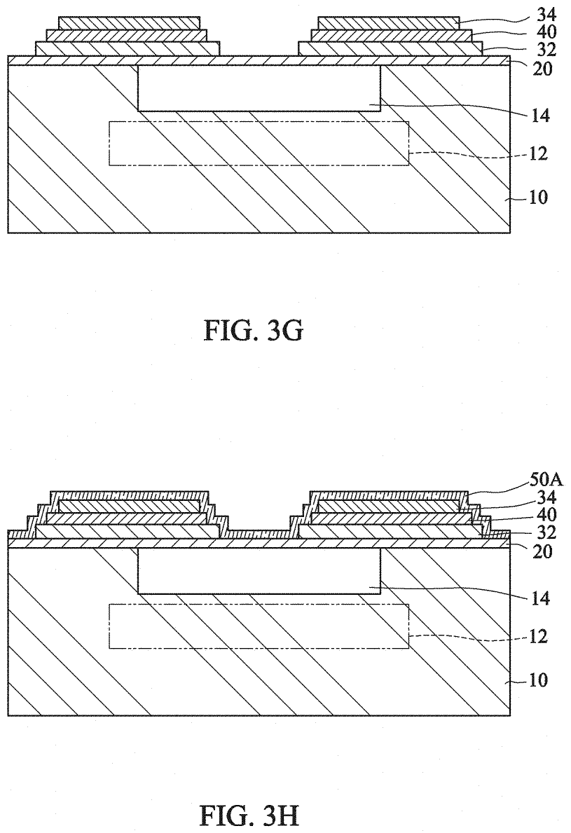

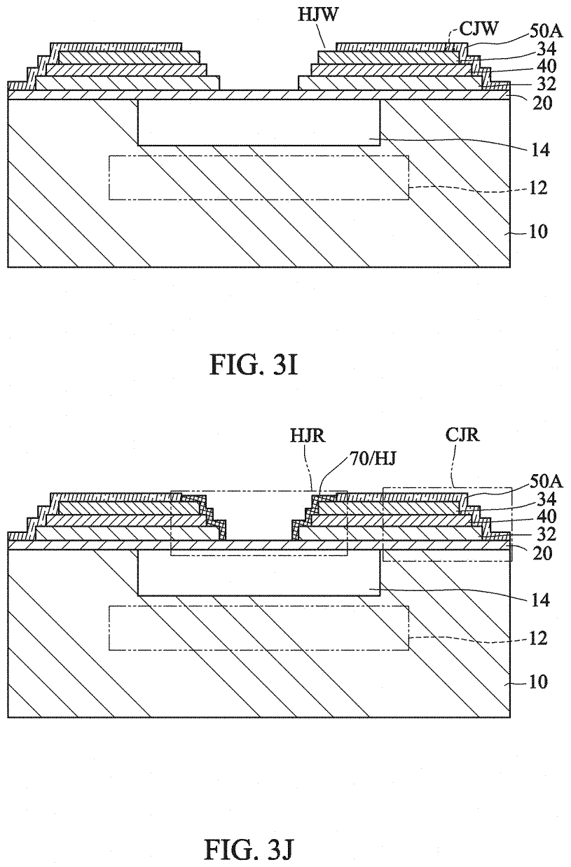

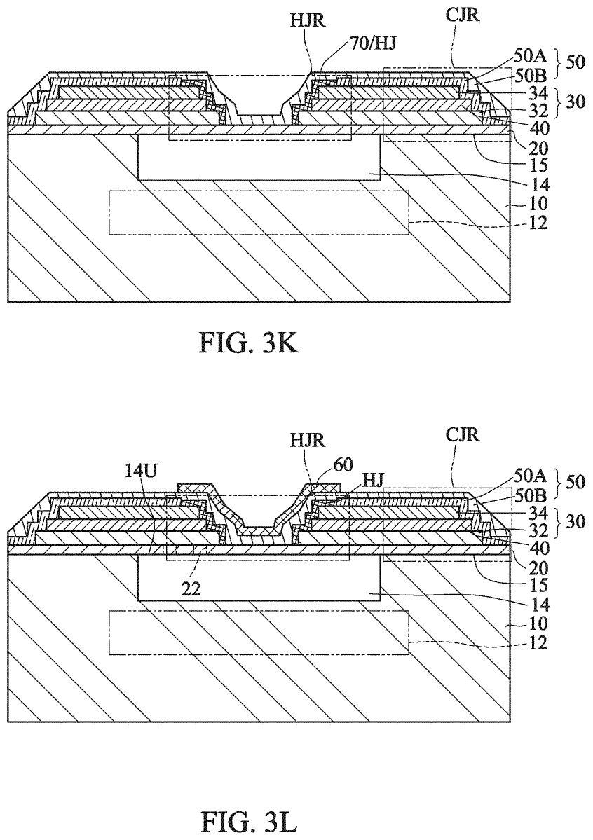

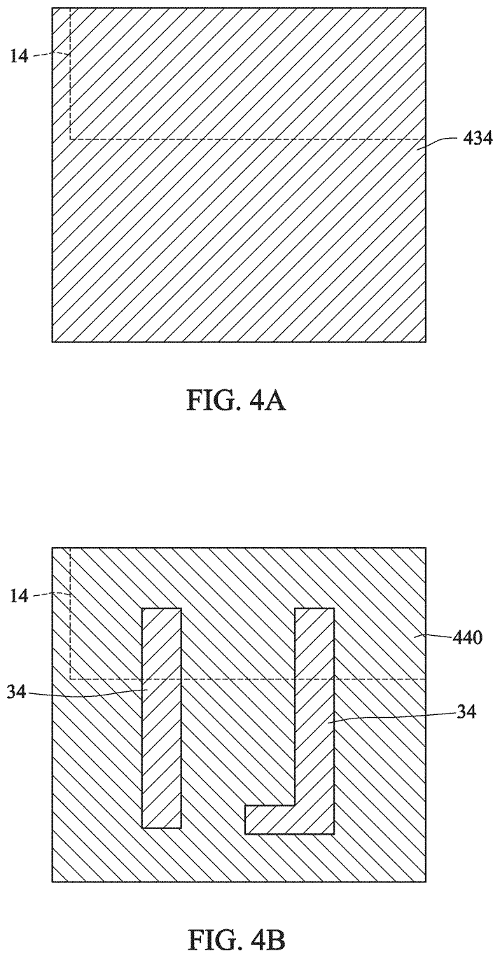

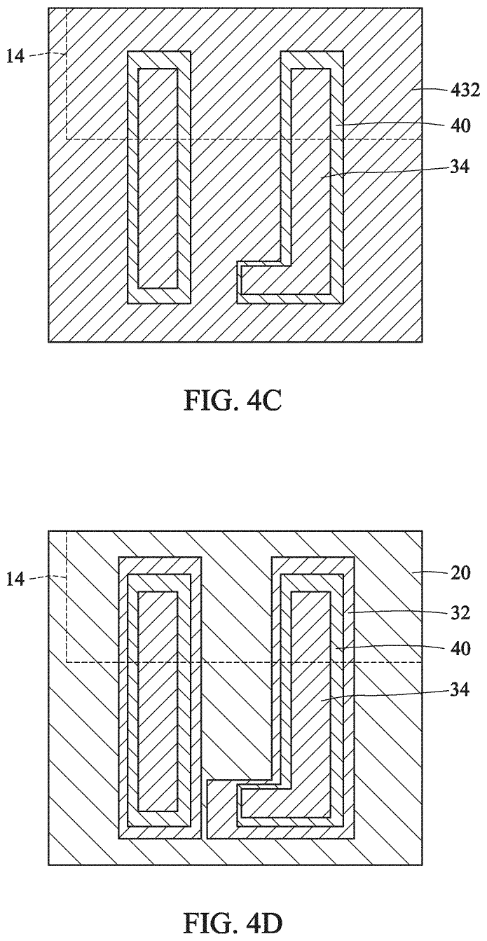

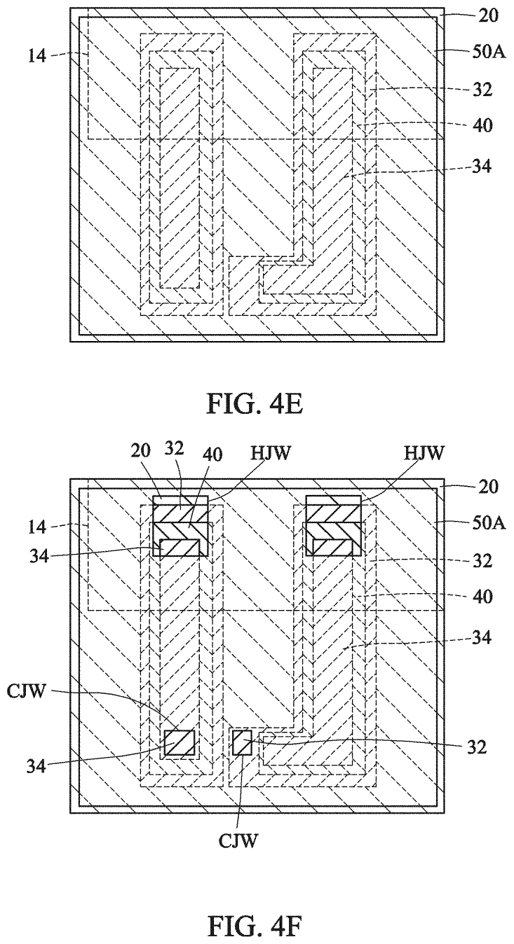

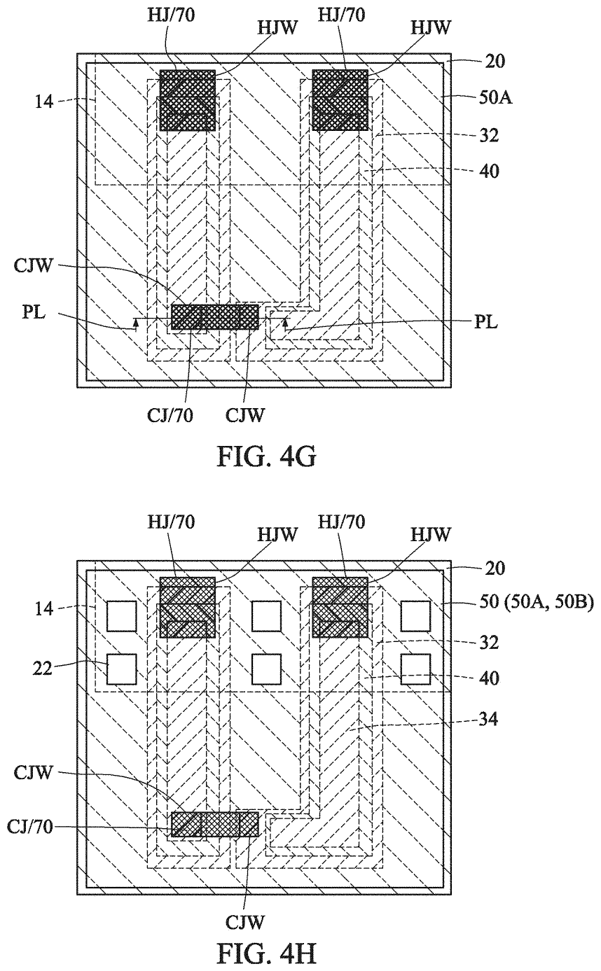

FIGS. 3A to 3L are schematically cross-sectional views showing structures taken along the line CL-CL of FIG. 1B corresponding to steps of the method of manufacturing the thermal infrared sensing member of the second embodiment. FIGS. 4A to 4H are partially enlarged schematic top views showing structures corresponding to some steps of the method of manufacturing the thermal infrared sensing member of the second embodiment. As shown in FIG. 3A, a first initial structure 300 and a second initial structure 400 are provided. The first initial structure 300 includes a substrate 10 having a sensing circuit 12 and a chamber 14, and the sensing circuit 12 is disposed below or under the chamber 14. The substrate 10 can be used to form the sensing circuit 12 and the chamber 14, and this can be easily achieved in the semiconductor manufacturing process. In addition to the circuit (circuitry), the sensing circuit 12 also has metal interconnections. A thin insulating layer (not shown), such as a silicon dioxide layer, may also be formed on the substrate 10.

The second initial structure 400 includes: a first insulating layer 20; a first conductor layer 432, which may be monocrystalline silicon, polysilicon or any other material suitable for the thermal couple, and is disposed on the first insulating layer 20; a dielectric layer 440 disposed on the first conductor layer 432; a second conductor layer 434, which may be monocrystalline silicon, polysilicon or any other material suitable for the thermal couple, and is disposed on the dielectric layer 440; a second dielectric layer 450 disposed on the second conductor layer 434; and a second substrate 410 disposed on the second dielectric layer 450. That is, the second substrate 410 is disposed above the dielectric layer 440. Thus, the second substrate 410 can be used to form the second dielectric layer 450, the second conductor layer 434, the dielectric layer 440, the first conductor layer 432 and the first insulating layer 20 in order, and then the second initial structure 400 is inverted into the state shown in FIG. 3A. Each of the second dielectric layer 450, the second conductor layer 434, the dielectric layer 440, the first conductor layer 432 and the first insulating layer 20 is an integral sheet structure. Consequently, the first initial structure 300 and the second initial structure 400 need not to be precisely aligned.

As shown in FIG. 3B, the first insulating layer 20 of the second initial structure 400 and the substrate 10 of the first initial structure 300 are bonded together, so that the first insulating layer 20 is disposed on the substrate 10, and covers the chamber 14 to serve as an upper wall surface 14U of the chamber 14, and a bonding interface 15 is formed between the first insulating layer 20 and the substrate 10, and similar to the embodiment of FIG. 2B. As mentioned hereinabove, the materials of the thermal couple 30 (the materials of the first conductor layer 432 and the second conductor layer 434) are formed on another substrate (second substrate 410) and transferred to a location above the chamber 14 by way of bonding.

As shown in FIGS. 3C and 3D, the second substrate 410 and the second dielectric layer 450 are removed. At this time, the top view corresponds to FIG. 4A, wherein only a portion of the chamber 14 is shown. As shown in FIG. 3E, the second conductor layer 434 is patterned using, for example, the photoresist for exposure, etching and the like, to form second conductors 34 disposed on the dielectric layer 440. At this time, the top view corresponds to FIG. 4B. As shown in FIG. 3F, the dielectric layer 440 is patterned to form a second insulating layer 40 disposed on the first conductor layer 432. At this time, the top view corresponds to FIG. 4C. As shown in FIG. 3G, the first conductor layer 432 is patterned to form first conductors 32 disposed on the first insulating layer 20. At this time, the top view corresponds to FIG. 4D.

As shown in FIG. 3H, a first sub-protection layer 50A is formed on the first conductors 32, the second conductors 34 and the first insulating layer 20. At this time, the top view corresponds to FIG. 4E. It is worth noting that only a portion of the first sub-protection layer 50A, which does not cover the entire first insulating layer 20, is depicted in order to avoid any confusion. As shown in FIG. 3I, the first sub-protection layer 50A is patterned to form hot junction windows HJW and cold junction windows CJW. At this time, the top view corresponds to FIG. 4F, wherein the hot junction windows HJW expose a portion of the first insulating layer 20 (optional), the first conductor 32, the second conductor 34 and the second insulating layer 40 (optional). As shown in FIG. 3J, connection conductors 70 are formed in the hot junction windows HJW and the cold junction windows CJW, the second conductors 34 are electrically connected to the first conductors 32 through the hot junction windows HJW and the cold junction windows CJW to form thermal couples 30, and the thermal couples 30 are serially connected together to form the thermopile. Each thermal couple 30 includes the first conductor 32 and the second conductor 34 disposed above the first conductor 32. The first conductor 32 and the second conductor 34 of each thermal couple 30 are connected at a hot junction region HJR disposed above the chamber 14. The two adjacent thermal couples 30 are connected at a cold junction region CJR away from the chamber 14. At this time, the top view corresponds to FIG. 4G. The material of the first conductor 32 is, for example, silicon, such as P/N-type polysilicon. The material of the second conductor 34 is, for example, silicon, such as N/P-type polysilicon, having the positive/negative Seedback coefficient to increase the Seedback voltage and increase the sensitivity. It is worth noting that although the depicted hot junction HJ has a steep ladder-like structure, the actual hot junction HJ should have the tilt-angle surface structure upon manufacturing.

The steps in FIGS. 3H to 3J can be generalized as follows. The first conductors 32 and the second conductors 34 are used to form the thermal couples 30. The thermal couples 30 are serially connected together to form the thermopile. Each thermal couple 30 includes the first conductor 32 and the second conductor 34 disposed above the first conductor 32. The first conductor 32 and the second conductor 34 of each thermal couple 30 are connected at a hot junction region HJR disposed above the chamber 14. The two adjacent thermal couples 30 are connected at a cold junction region CJR away from the chamber 14. It is worth noting that the connection conductor 70 may also be considered as a portion of the second conductor 34. That is, each second conductor 34 has two sections having different materials so as to have the synthetic characteristics that can be generalized with the structure of FIG. 2J.

As shown in FIG. 3K, a second sub-protection layer 50B is formed on the first sub-protection layer 50A and the connection conductors 70 (serving as the hot junction HJ and the cold junction CJ), and the first sub-protection layer 50A and the second sub-protection layer 50B constitute a protection layer 50 covering the hot junction region HJR and the cold junction region CJR. At this time, the top view corresponds to FIG. 4H.

As shown in FIG. 3L, a black body layer 60 is formed on the protection layer 50, and the black body layer 60 for absorbing radiation heat covers the hot junction region HJR, but does not cover the cold junction region CJR. The steps in FIGS. 3C to 3L can be generalized as the sub-step of using the second initial structure 400 to form one or multiple thermal couples (or one thermopile).

Please refer to FIGS. 1C and 3L, the manufacture method of the above-mentioned thermal infrared sensing member 100 may further include the following steps of: forming openings 22, which are disposed on the first insulating layer 20 and penetrate through the first insulating layer 20 to communicate with the chamber 14, thereby increasing the thermal resistance. If the protection layer 50 also covers the first insulating layer 20, then the openings 22 may further penetrate through the protection layer 50.

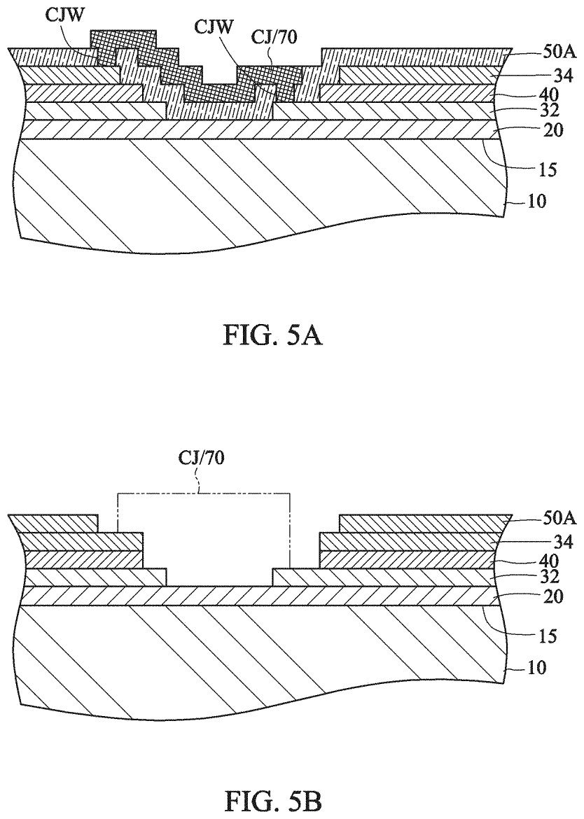

FIG. 5A is a schematically partial cross-sectional view showing the structure corresponding to the line PL-PL of FIG. 4G. As shown in FIG. 5A, the connection conductor 70 or the cold junction CJ establishes the electrical connection to the second conductor 34 on the left side, and to the first conductor 32 on the right side through the cold junction windows CJW of the first sub-protection layer 50A. This connection configuration is also applicable to the connection configuration of the hot junction HJ.

FIG. 5B is a schematically partial cross-sectional view showing the structure of the modified example corresponding to FIG. 5A. The structure of FIG. 5B is similar to that of FIG. 5A except for the difference that the second insulating layer 40 and the edge of the second conductor 34 are aligned, so the second conductor 34 can be used to serve as the mask of the second insulating layer 40, thereby decreasing the number of masks.

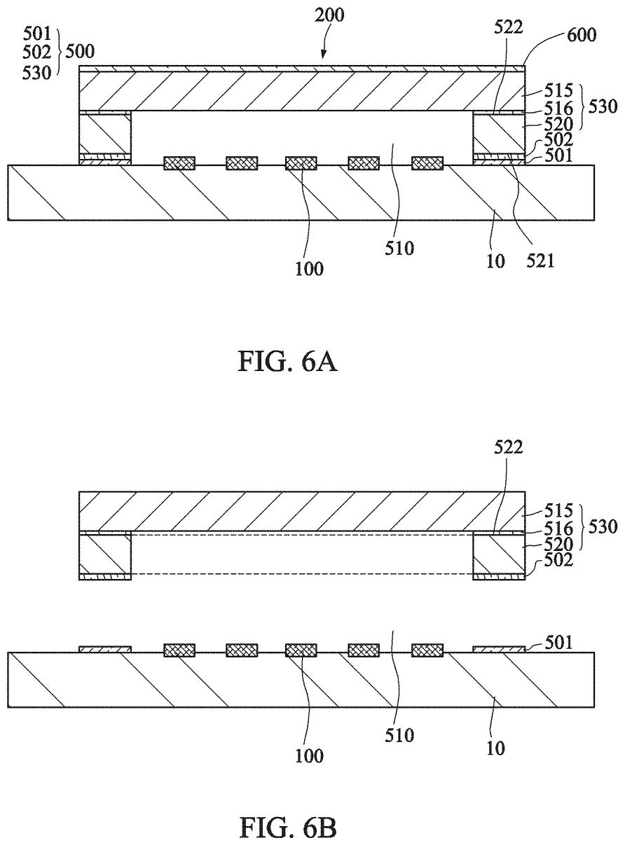

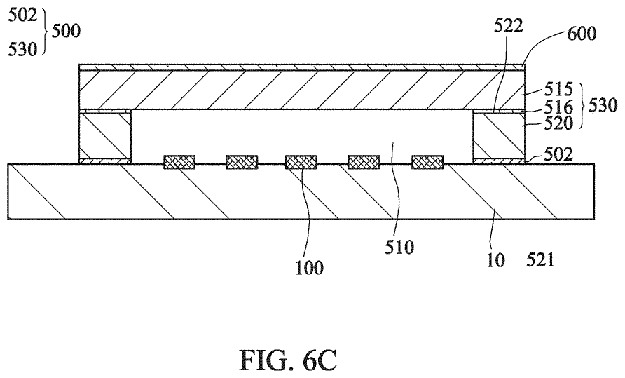

FIG. 6A is a schematically cross-sectional view showing the structure of a first modified example of the thermal infrared sensor of FIG. 1A. Referring to FIG. 6A, the thermal infrared sensor 200 further includes a cover layer 500 which has a cover cavity 510 and is bonded to the substrate 10, so that the thermal infrared sensing members 100 is accommodated within the cover cavity 510. In one example, the cover cavity 510 is in a vacuum state (the pressure is lower than one atmosphere) to increase the sensitivity of the thermal infrared sensing members 100. The thermal infrared sensor 200 may further include a band pass filter layer 600 disposed on the cover layer 500, and perform the band pass filtering operation on the electromagnetic waves entering the cover cavity 510 from the outside. For example, only the infrared can pass therethrough. In one example, the thickness of the band pass filter layer 600 ranges between 8 and 14 microns, and is an infrared filter.

FIG. 6B is a schematically cross-sectional view showing bonding of the thermal infrared sensor of FIG. 6A. As shown in FIGS. 6B and 6A, the cover layer 500 includes: a first bonding layer 501 disposed on the substrate 10; a second bonding layer 502; and a cover substrate 530 having the cover cavity 510, a body 515 disposed above the cover cavity 510, and a frame 520 disposed around the cover cavity 510. The second bonding layer 502 is disposed on a bottom surface 521 of the frame 520, and the second bonding layer 502 and the first bonding layer 501 are bonded together. In this example, a top surface 522 of the body 515 is bonded to the frame 520 by an oxide layer (e.g., a semiconductor oxide layer of a silicon dioxide layer) 516. In this example, the material of the body 515 is monocrystalline silicon (wafer), the material of the frame 520 is polysilicon, the first bonding layer 501 and the second bonding layer 502 may include aluminum and germanium, which may form eutectic bonding at about 420° C., are compatible with the CMOS manufacturing process and are more suitable for application in the integrated design of this embodiment. In another condition, the first bonding layer may be omitted, and the silicon material of the substrate 10 itself may serve as the material of the bonding layer. In this case, the material of the second bonding layer may be gold (Au). In FIG. 6B, the lower surface of the body 515 is formed with the oxide layer 516, and then the lower surface of the oxide layer 516 is formed with the polysilicon layer (patterned to form the frame 520, wherein the dashed lines show the removed portion). Then, the exposed oxide layer 516 is removed, and the lower surface of the frame 520 is formed with the germanium layer (the second bonding layer 502). The second bonding layer 502 and the aluminum layer on the upper surface of the substrate 10 are bonded together. Upon bonding, the processing chamber is vacuumed so that the cover cavity 510 after bonding is in the vacuum state. The bonding technology may include the wafer level chip scale package (WLCSP).

FIG. 6C is a schematically cross-sectional view showing a second modified example of the thermal infrared sensor of FIG. 1A. As shown in FIG. 6C, both of the cover layer 500 and the substrate 10 form the interface having the structural strength of the hydrogen bonds by way of low temperature fusion bonding. Of course, before the low temperature fusion bonding is formed, the surface plasma treatment may be further performed in order to achieve the surface activation. For example, the surface plasma treatment may be performed in the plasma environment of oxygen (O₂) and nitrogen (N₂). In order to make the bonded surface have good flatness, chemical-mechanical polishing (CMP) may be performed to polish and planarize the to-be-bonded surface. The precursor of the cover layer 500 may be a silicon-on-insulator (SOI) wafer. The lower wafer is etched to form the cover cavity 510, and the oxide layer 516 may also be removed. Then, the second bonding layer 502 (may be a silicon dioxide layer) is bonded to the substrate 10. It is noted that the bonding is different from the combination by an adhesive.

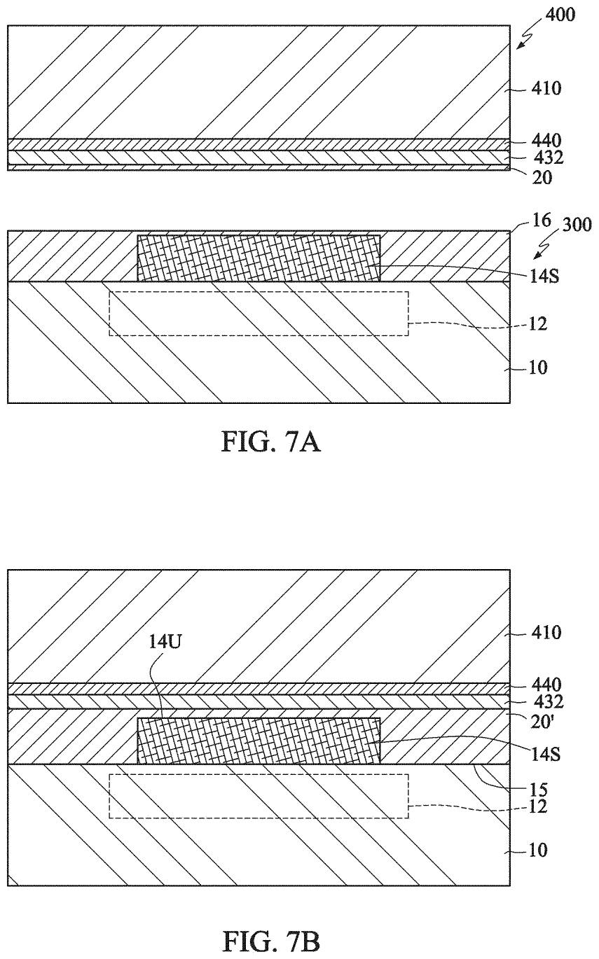

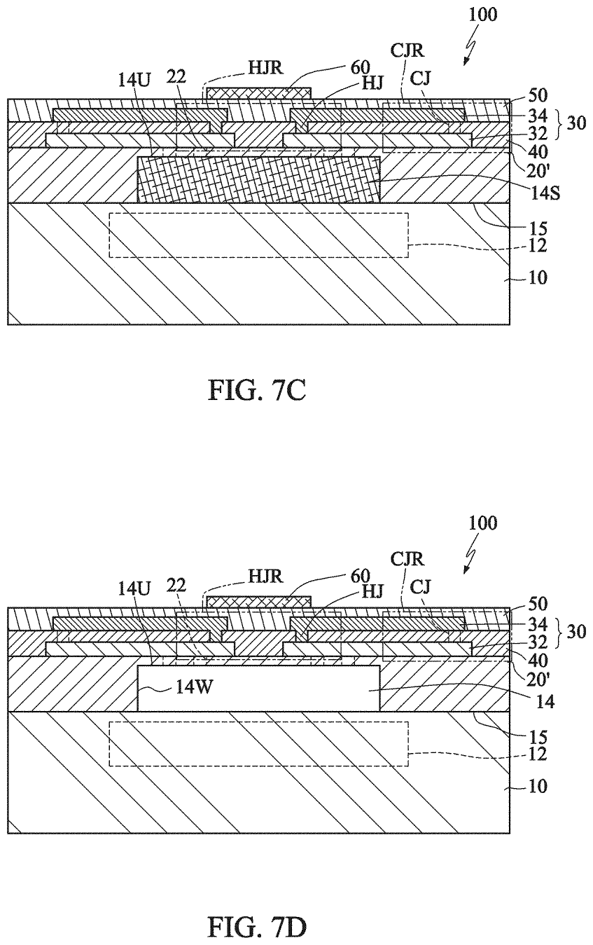

As shown in FIGS. 7A to 7D, the third embodiment of this disclosure provides a method of manufacturing the heterogeneously integrated thermal infrared sensing member 100. The method includes the following steps. First, as shown in FIG. 7A, a first initial structure 300 and a second initial structure 400 are provided. The first initial structure 300 includes: a substrate 10 having a sensing circuit 12; a sacrificial layer 14S disposed on the substrate 10; and a protection bonding layer 16 covering the sacrificial layer 14S and the substrate 10. The sensing circuit 12 is disposed below or under the sacrificial layer 14S. The second initial structure 400 includes: a first conductor layer 432; a dielectric layer 440 disposed on the first conductor layer 432; and a second substrate 410 disposed on or above the dielectric layer 440. After the protection bonding layer 16 has covered the sacrificial layer 14S, the protection bonding layer 16 can be ground to obtain the flat surface and control the required thickness.

Then, as shown in FIG. 7, the second initial structure 400 and the first initial structure 300 are bonded together with the substrate 10 and the second substrate 410 being disposed away from each other to obtain a bonded first insulating layer 20′ being disposed on the substrate 10 and covering the sacrificial layer 14S.

The following steps of the manufacturing method are similar to those of FIGS. 2C to 2H. That is, the second initial structure 400 is used to form the thermopile. No similar drawings will be provided here.

Then, as shown in FIG. 7C, openings 22 are formed on the bonded first insulating layer 20′ to expose the sacrificial layer 14S, and the material of the sacrificial layer 14S includes, for example but without limitation to the silicon material, metal material and the like. Next, as shown in FIG. 7D, the sacrificial layer 14S is removed through the openings 22 to form a chamber 14, so that the chamber 14 is formed on the substrate 10, and the bonded first insulating layer 20′ is disposed on the substrate 10 and covers the chamber 14 to serve as an upper wall surface 14U and a sidewall surface 14W of the chamber 14. The openings 22 are communicated with the chamber 14 and an external environment and penetrate through the first insulating layer 20′ to communicate with the chamber 14, thereby increasing the thermal resistance, which is preferably larger, so the openings 22 need not to be closed by filling other materials. It is worth noting that the bonding interface 15 is also formed between the bonded first insulating layer 20′ and the substrate 10. In addition, the bonded first insulating layer 20′ is also regarded as the first insulating layer in the thermal infrared sensing member 100, and the first insulating layer further serves as the sidewall surface 14W of the chamber 14. In this case, the chamber 14 is formed on the substrate 10. Of course, the sacrificial layer 14S represents the technology of bonding the wafers together and then removing the sacrificial layer 14S to form the chamber. However, this disclosure is not restricted thereto, and any other method of forming the chamber may be deemed as falling within the scope of this disclosure as long as the spirit of this disclosure of integrating the heterogeneous structures. For example, the chamber may be formed by the metal silicide, such as NiSi.

Specifically speaking, the step of using the second initial structure 400 to form the thermopile includes the following sub-steps. As shown in FIGS. 7B and 2C to 2H (the chamber 14 is regarded as the sacrificial layer 14S), the second substrate 410 and the dielectric layer 440 are firstly removed. Next, the first conductor layer 432 is patterned to form first conductors 32 disposed on the bonded first insulating layer 20′. Then, the first conductors 32 are used to form thermal couples 30. The thermal couples 30 are serially connected together to form the thermopile. Each thermal couple 30 includes the first conductor 32 and a second conductor 34 disposed above the first conductor 32. The first conductor 32 and the second conductor 34 of each thermal couple 30 are connected at a hot junction region HJR disposed above the chamber 14. The two adjacent thermal couples 30 are connected at a cold junction region CJR away from the chamber 14, and two ends of the first one of the conductors 32 and the last one of the conductors 34 at the cold junction region CJR are electrically connected to the sensing circuit 12. Next, a protection layer 50 is formed on the second conductors 34 to cover the hot junction region HJR and the cold junction region CJR. Then, a black body layer 60 is formed on the protection layer 50. The black body layer 60 for absorbing radiation heat covers the hot junction region HJR, but does not cover the cold junction region CJR.

In addition, the step of using the first conductors 32 to form the thermal couples 30 includes the sub-steps of: forming a second insulating layer 40 on the first conductors 32 and the bonded first insulating layer 20′; patterning the second insulating layer 40 to form hot junction windows HJW and cold junction windows CJW; forming a second conductor layer 434 on the second insulating layer 40 so that the second conductor layer 434 is electrically connected to the first conductors 32 through the hot junction windows HJW and the cold junction windows CJW; and patterning the second conductor layer 434 to form the second conductors 34, wherein the first conductors 32 and the second conductors 34 form the thermal couples 30, the thermal couples 30 are serially connected together to form the thermopile, each thermal couple 30 includes the first conductor 32 and the second conductor 34 disposed above the first conductor 32, the first conductor 32 and the second conductor 34 of each thermal couple 30 are connected at the hot junction region HJR disposed above the chamber 14, and the two adjacent thermal couples 30 are connected at the cold junction region CJR away from the chamber 14.

In FIGS. 7A and 7B, the second initial structure 400 further includes a first insulating layer 20, wherein the first conductor layer 432 is disposed on the first insulating layer 20, and the first insulating layer 20 of the second initial structure 400 and the protection bonding layer 16 of the first initial structure 300 are bonded together to obtain the bonded first insulating layer 20′.

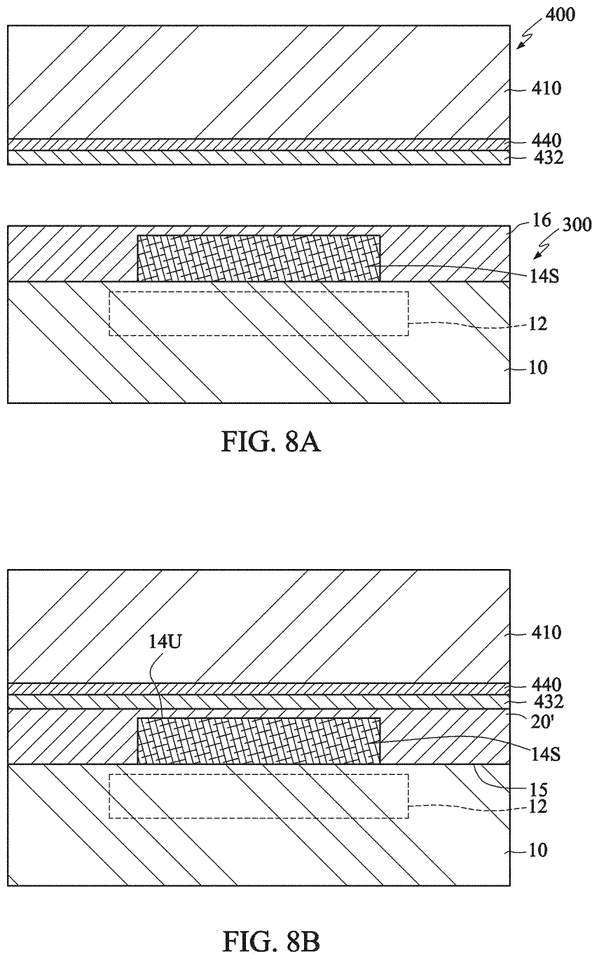

In FIGS. 8A and 8B, the second initial structure 400 does not have the first insulating layer 20, and thus the first conductor layer 432 of the second initial structure 400 and the protection bonding layer 16 of the first initial structure 300 are bonded together, so that the protection bonding layer 16 becomes the bonded first insulating layer 20′.

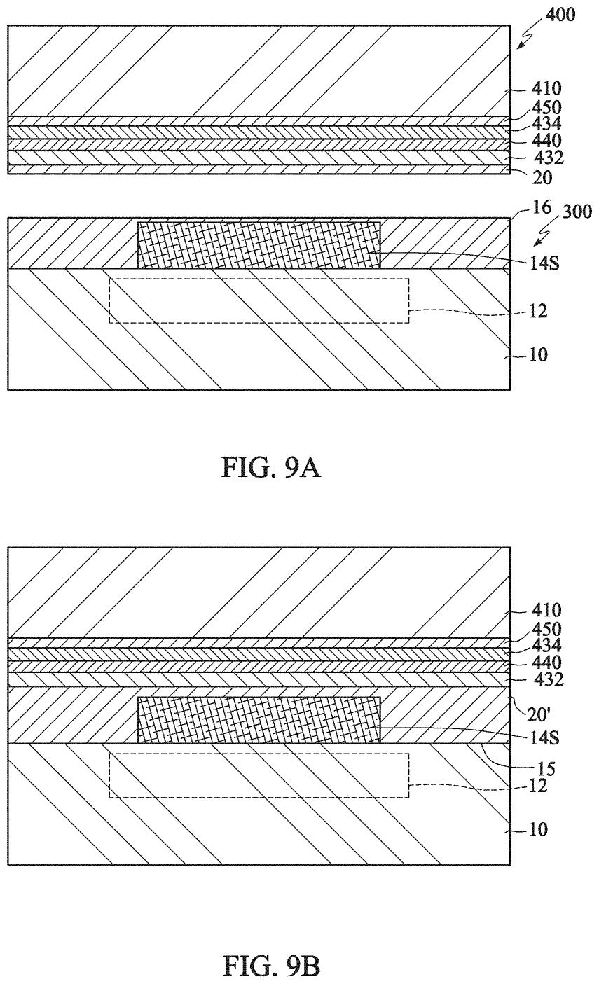

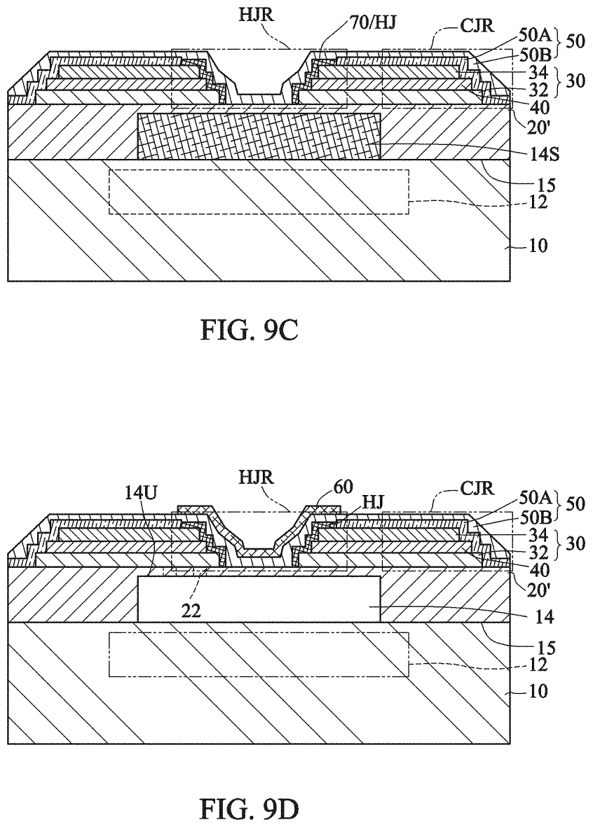

As shown in FIGS. 9A to 9D in conjunction with FIGS. 3A to 3L (with the difference that the chamber 14 is regarded as the sacrificial layer 14S), the fourth embodiment of this disclosure is similar to the third embodiment and also provides a method of manufacturing the heterogeneously integrated thermal infrared sensing member 100, wherein the difference resides in that the second initial structure 400 further includes: a second conductor layer 434 disposed on the dielectric layer 440; and a second dielectric layer 450 disposed on the second conductor layer 434, wherein the second substrate 410 is disposed on the second dielectric layer 450. Therefore, the step of using the second initial structure 400 to form the thermopile includes the following sub-steps: removing the second substrate 410 and the second dielectric layer 450; patterning the second conductor layer 434 to form second conductors 34 disposed on the dielectric layer 440; patterning the dielectric layer 440 to form a second insulating layer 40 disposed on the first conductor layer 432; patterning the first conductor layer 432 to form first conductors 32 disposed on the bonded first insulating layer 20′; using the first conductors 32 and the second conductors 34 to form thermal couples 30, wherein the thermal couples 30 are serially connected together to form the thermopile, each thermal couple 30 includes the first conductor 32 and the second conductor 34 disposed above the first conductor 32, the first conductor 32 and the second conductor 34 of each thermal couple 30 are connected at a hot junction region HJR disposed above the chamber 14, the two adjacent thermal couples 30 are connected at a cold junction region CJR away from the chamber 14, two ends of the first one of the conductors 32 and the last one of the conductors 34 at the cold junction region CJR are electrically connected to the sensing circuit 12, and the second conductor 34 is covered by a first sub-protection layer 50A; and forming a second sub-protection layer 50B on the first sub-protection layer 50A and the hot junction region HJR and the cold junction region CJR, wherein the first sub-protection layer 50A and the second sub-protection layer 50B form the protection layer 50 covering the hot junction region HJR and the cold junction region CJR. In addition, the step of using the first conductors 32 and the second conductors 34 to form the thermal couples 30 includes: forming the first sub-protection layer 50A on the first conductors 32, the second conductors 34 and the bonded first insulating layer 20′; patterning the first sub-protection layer 50A to form hot junction windows HJW and cold junction windows CJW; and forming connection conductors 70 in the hot junction windows HJW and the cold junction windows CJW, wherein the second conductors 34 are electrically connected to the first conductors 32 through the hot junction windows HJW and the cold junction windows CJW to form thermal couples 30, the thermal couples 30 are serially connected together to form the thermopile, each thermal couple 30 includes the first conductor 32 and the second conductor 34 disposed above the first conductor 32, the first conductor 32 and the second conductor 34 of each thermal couple 30 are connected at the hot junction region HJR disposed above the chamber 14, the two adjacent thermal couples 30 are connected at the cold junction region CJR away from chamber 14, and the hot junctions HJ and the cold junctions CJ pertain to the connection conductors 70.

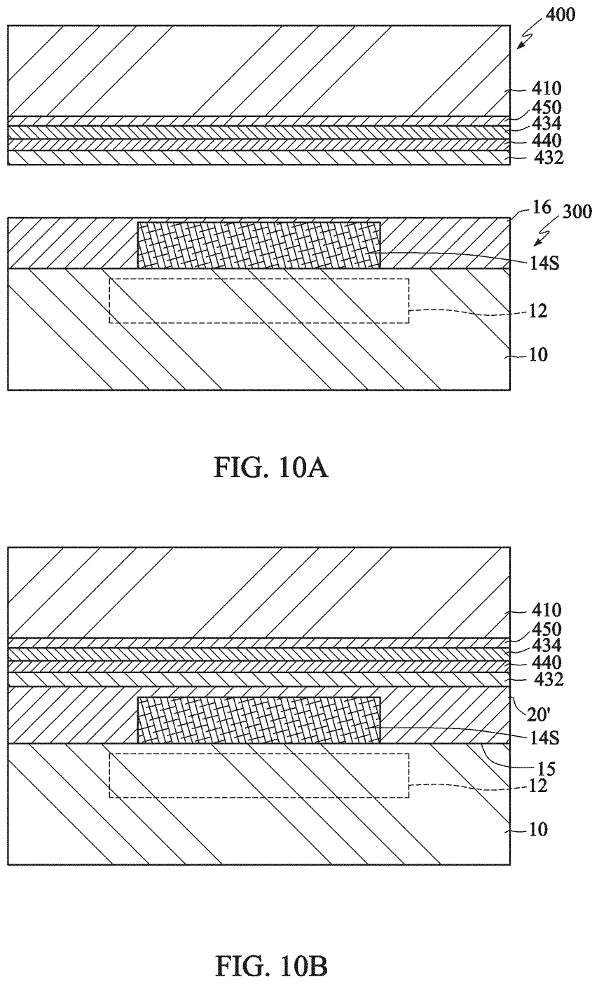

As shown in FIGS. 10A and 10B, the modified example is similar to FIGS. 9A and 9B except for the difference residing in that the second initial structure 400 in FIG. 10A does not have the first insulating layer 20. Therefore, the first conductor layer 432 of the second initial structure 400 and the protection bonding layer 16 of the first initial structure 300 are bonded together to make the protection bonding layer 16 become the bonded first insulating layer 20′.

To sum up with reference to FIGS. 2A to 2J and FIGS. 3J to 3L, this disclosure provides a heterogeneously integrated thermal infrared sensing member 100 including a substrate 10; a chamber 14 disposed in or on the substrate 10; and one or multiple thermal couples 30 formed using materials (elements 20, 432, 440, 434 and 450) formed on a sacrificial substrate 410 and transferred to a location above the chamber 14 by way of bonding the substrate 10 to one portion (element 20) of the materials formed on the sacrificial substrate 410, removing the sacrificial substrate 410, and patterning and interconnecting another portion of the materials (elements 432 and 434), wherein the thermal couple 30 or each of the thermal couples 30 includes a first conductor 32 and a second conductor 34, first ends of the first conductor 32 and the second conductor 34 of the thermal couple 30 are connected at a hot junction region HJR disposed above the chamber 14, and second ends of the first conductor 32 and the second conductor 34 of the thermal couple 30 are located at a cold junction region CJR disposed around the chamber 14.

Therefore, the spirit of the embodiment of this disclosure is to bond two wafers together especially by way of blind bonding to manufacture the thermal infrared sensing member and thermal infrared sensor, wherein the lower wafer (the first initial structure 300) is processed using the CMOS manufacturing process to form the circuit/circuitry and cavity, and the upper wafer (the second initial structure 400) is processed using, for example, the polysilicon manufacturing process. The two wafers are formed in different manufacturing process conditions, and are bonded together so that the patterning and interconnect formation processes can be performed. So, the circuit/circuitry is free from being destroyed by the too-high temperature in the manufacturing process. The sensing circuit includes transistors and metal interconnections, and will be destroyed by the high-temperature manufacturing processes of forming the polysilicon layer or layers of the first conductor and the second conductor (the material of at least one of the first conductor and the second conductor of the thermal couple includes the high-temperature polysilicon). In another example, the monocrystalline silicon of the SOI wafer can be used to serve as the material of at least one of the first conductor and the second conductor. Because the circuit/circuitry (e.g., the integrated MOS FET and the metal wires) can be formed under the chamber without being affected by the high-temperature manufacturing process for the thermal couple material, the fill factor (FF) can be very high, and at least greater than 30% in an example having a pitch of 30 microns (μm), and the chamber length of 20 μm, or even greater than 50%. Also, based on this scheme, it can support a higher density array device with pixel pitch smaller than 30 μm or even 20 μm. That is, the thermal infrared sensing members are arranged to have a pixel pitch smaller than 30 μm or even 20 μm. The signal transmission path is shortened, and the signal-to-noise ratio is increased. In addition, the heterogeneous integration technology makes it possible to stack the polysilicon, which requires the high-temperature manufacturing process, above or on the CMOS wafer.

While this disclosure has been described by way of examples and in terms of preferred embodiments, it is to be understood that this disclosure is not limited thereto. To the contrary, it is intended to cover various modifications. Therefore, the scope of the appended claims should be accorded the broadest interpretation so as to encompass all such modifications.

What is claimed is:

1. A heterogeneously integrated thermal infrared sensing member, comprising:
a substrate;
a chamber disposed in or on the substrate; and
one or multiple thermal couples formed using materials formed on a sacrificial substrate and transferred to a location above the chamber by way of bonding the substrate to one portion of the materials formed on the sacrificial substrate, removing the sacrificial substrate, and patterning and interconnecting another portion of the materials, wherein the thermal couple or each of the thermal couples comprises a first conductor and a second conductor, first ends of the first conductor and the second conductor of the thermal couple are connected at a hot junction region disposed above the chamber, and second ends of the first conductor and the second conductor of the thermal couple are located at a cold junction region disposed around the chamber.

2. The heterogeneously integrated thermal infrared sensing member according to claim 1, further comprising an insulating layer being disposed on the substrate and covering the chamber to serve as an upper wall surface of the chamber, wherein a bonding interface is formed between the insulating layer and the substrate.

3. The heterogeneously integrated thermal infrared sensing member according to claim 2, wherein the insulating layer is formed with multiple openings penetrating through the insulating layer and communicating with the chamber.

4. The heterogeneously integrated thermal infrared sensing member according to claim 2, wherein the insulating layer further serves as sidewall surfaces of the chamber.

5. The heterogeneously integrated thermal infrared sensing member according to claim 1, wherein one or multiple ones of the first conductor and the second conductor are made of a material comprising silicon.

6. The heterogeneously integrated thermal infrared sensing member according to claim 1 having a fill factor greater than 30%.

7. The heterogeneously integrated thermal infrared sensing member according to claim 1, further comprising a sensing circuit disposed in or on the substrate, wherein the sensing circuit is disposed below the chamber, and the one or multiple thermal couples are electrically connected to the sensing circuit.

8. The heterogeneously integrated thermal infrared sensing member according to claim 7, wherein the sensing circuit comprises transistors and metal interconnections.

9. A thermal infrared sensor, comprising multiple ones of the heterogeneously integrated thermal infrared sensing members according to claim 1, wherein the heterogeneously integrated thermal infrared sensing members are arranged in a two-dimensional array to sense a thermal image, and share the substrate.

10. The thermal infrared sensor according to claim 9, further comprising:
a cover layer having a cover cavity and being bonded to the substrate, so that the heterogeneously integrated thermal infrared sensing members are accommodated within the cover cavity.

11. The thermal infrared sensor according to claim 10, wherein the cover cavity is in a vacuum state lower than one atmospheric pressure to increase sensitivities of the heterogeneously integrated thermal infrared sensing members.

12. The thermal infrared sensor according to claim 10, further comprising:
a band pass filter layer which is disposed on the cover layer and performs band pass filtering operations on external electromagnetic waves entering the cover cavity.

13. The thermal infrared sensor according to claim 10, wherein the cover layer comprises:
a first bonding layer disposed on the substrate;
a second bonding layer; and
a cover substrate having the cover cavity, a body disposed above the cover cavity, and a frame surrounding the cover cavity, wherein the second bonding layer is disposed on a bottom surface of the frame, and the second bonding layer and the first bonding layer are bonded together.

14. The thermal infrared sensor according to claim 9, wherein the heterogeneously integrated thermal infrared sensing members are arranged to have a pixel pitch smaller than 30 μm.
